(19) United States
(12) Patent Application Publication
(10) Pub. No.: US 2004/0150052 A1
(43) Pub. Date: Aug. 5, 2004

(54) Integrated electronic device and manufacturing method thereof

(76) Inventors: Damiano Riccardi, Cavenago Brianza (IT); Giuseppe Croce, Concorezzo (IT); Alessandro Moscatelli, Como (IT); Paolo Fantini, Carpi (IT)

Correspondence Address: GRAYBEAL, JACKSON, HALEY LLP, 155 - 108TH AVENUE NE, SUITE 350, BELLEVUE, WA, 98004-5901, US

(21) Appl. No.: 10/737,721

(22) Filed: Dec. 15, 2003

(30) Foreign Application Priority Data
Dec. 13, 2002 (IT) MI2002A002634

(51) Int. Cl. H01L 29/76

(52) U.S. Cl. 257/369

(57) ABSTRACT

Electronic circuit integrated in a chip of semiconductor material comprising a first buried channel MOS transistor and a second MOS transistor, of a type complementary to the first transistor, both made in said chip in CMOS technology. Particularly, also the second transistor is of a buried channel type.

The conductive channel of said N-MOS and P-MOS transistors is located inside of a respective doped layer, at a pre-selected distance from the interface between said doped layer and a gate oxide layer. Such technological characteristic, improving the reduction of the low frequency noise, makes buried channel transistors particularly useful in the manufacturing of input circuit blocks in audio amplifiers.

### PRIORITY CLAIM

This application claims priority from Italian patent application No. M12002A002634, filed Dec. 13, 2002, which is incorporated herein by reference.

### TECHNICAL FIELD

The present invention relates to an electronic device including field effect MOS transistors in CMOS technology and a method for the manufacturing thereof.

### BACKGROUND

Presently the CMOS (Complementary Metal-Oxide-Semiconductor) technology is the most used for the manufacturing of surface channel MOS transistors. As a matter of fact CMOS technology allows to integrate, at the same time N type surface channel MOS transistors (N-MOS) and P type surface channel MOS transistors (P-MOS) on the same support structure, typically a silicon chip. Further, the recent developments of CMOS technology such as VLSI and ULSI (Very and Ultra Large Scale Integration) technologies have allowed to integrate, on the same chip, an ever increasing number of MOS, transistors reducing the physical size of each of them and producing advantages when the transistors are used in circuits which have to operate at high speed, such as digital circuits. As a matter of fact, small size MOS transistors show a small capacitive effect (e.g.: a reduced capacitance between gate and channel) and, consequently ensure high operating frequencies.

To integrated electronic devices which include MOS transistors and which are used for analog applications such as, for instance, audio amplifiers, it is required not so much a high operating frequency but, overall, a reduced noise at low frequency.

Electronic devices such as audio amplifiers are generally made connecting in cascade several circuit blocks, each of them includes a suitable number of transistors. The noise reduction is a specifically relevant need for the circuit block which is the input to the audio amplifier.

Conventional MOS transistors, that is surface channel transistors (surface channel MOS) show in general unsatisfactory performances in terms of noise. The reason of the noise generation at low frequency in a surface channel MOS (also called flicker noise or noise proportional to 1/f) is to be found in the interaction of the charge carriers present in the transistor channel with the surface layers of the upper interface between silicon and the gate dioxide (SiO2).

It is known that buried channel MOS transistors (buried channel MOS or in short, buried MOS), wherein the maximum concentration of the carriers in the channel takes place at a preselected distance from the interface between silicon and gate dioxide, show a reduced noise at low frequency.

According to a conventional manufacturing process of CMOS technology transistors as LSI (Large Scale Integration) technology, preceding historically VLSI and ULSI technologies, the integration is made in a silicon chip of a buried channel P-MOS transistor (buried P-MOS) and of a surface channel N-MOS transistor (surface N-MOS) having in common the doping type of the respective layers of gate polysilicon.

Specifically the gate polysilicon layers of both transistors are heavily doped with the same dopant (for instance phosphorus) in such a way as to make them of N+ type. Further, for the realization of the buried channel P-MOS transistor, inside the channel region of the P-MOS transistor itself is made an implantation of a P type layer.

As known, a buried layer P-MOS transistor shows a charge carriers mobility, that is holes, greater than that of surface channel P-MOS transistor.

In general, the LSI technology, because of the limited level of scalability which may be reached through it is now of a scarce interest.

### SUMMARY

According to an aspect of the present invention an electronic integrated device overcomes the drawbacks of the devices made with the aforementioned conventional technologies and which, in particular, is capable of offering improved performances with respect to the noise at low frequency and to mobility.

According to an aspect of the present invention a manufacturing method of an integrated electronic device is defined in claim 11.

### BRIEF DESCRIPTION OF THE DRAWINGS

Characteristics and advantages of the present invention will be better understood by the detailed description of one of its embodiments given in an illustrative and not limitative way in accordance to the attached drawings, wherein:

FIG. 1 shows schematically an electronic device made in CMOS technology according to an embodiment of the invention;

FIG. 2 shows schematically an energy bands diagram for a N-MOS transistor according to an embodiment of the invention;

FIGS. 3a and 3b show comparative diagrams of electrons concentration in a buried channel N-MOS transistor and in a surface channel N-MOS transistor;

FIGS. 4 and 5 show the steps of a specific manufacturing method of an electronic device according to an embodiment of the invention;

FIG. 6 shows manufacturing steps of a gate electrode for the N-MOS transistor and the P-MOS transistor of the electronic device according to one embodiment of said method;

FIG. 7 shows said electronic device including lightly doped regions according to an embodiment of the present invention;

FIGS. 8 and 9 show manufacturing steps of dielectric spacers according to an embodiment of said method;

FIG. 10 shows a manufacturing step of the source and drain pockets of the N-MOS transistor and the doping of the gate polysilicon of the P-NOS transistor according with an embodiment of said method;

FIG. 11 shows the electronic device completed with gate, source and drain contacts according to an embodiment of the invention;

FIG. 12 is a comparative graph of the effective electrons mobility in a buried channel N-MOS transistor according to an embodiment of the invention and in a surface channel N-MOS transistor;

FIG. 13 is a comparative graph of the noise spectral density in a buried channel N-MOS transistor according to an embodiment of the invention and in a surface channel N-MOS transistor.

### DETAILED DESCRIPTION

The following discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

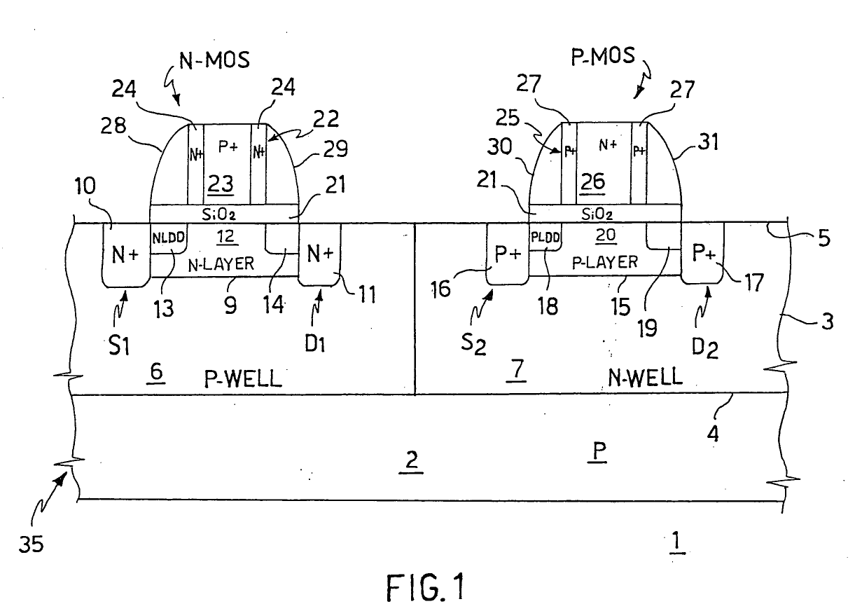

FIG. 1 shows a specific example of electronic device made according to an embodiment the invention comprising at least two buried channel transistors complementary with each other that is, at least one N type buried channel N-MOS transistor and at least one P type buried channel transistor.

In greater detail, device 1 is integrated in semiconductor material chip 35 (for example, silicon) comprising a P type substrate (or body) 2 and an epitaxial layer 3, located over a limit surface 4 of said substrate. The epitaxial layer 3 defines an upper surface 5 of chip 35, facing the limit surface 4.

Further, the epitaxial layer 3 comprises a first well doped region 6 and a second well doped region 7, having a doping and a conductivity of a type opposite to the first one. For instance, the first well doped region 6 is a P type region, while the second well doped region 7 is an N type region. In the following, for short, the two well regions 6 and 7 will also be called P-well and N-well regions respectively. Both P-well 6 and N-well 7 regions extend inside the epitaxial layer 3.

The N-MOS transistor is formed in the P-well region, while the P-MOS transistor is formed in the N-well region.

The N-MOS transistor comprises active regions (of N type) as a source region S1 and a drain region D1 which extend from the upper surface 5 inside the P-well region 6 and have a doping opposite to that of such a region. The source S1 region (drain D1) comprises a highly doped N+ type source pocket 10 (of drain 11) and a lightly doped first N type source region 13 (second region) (of drain 14), also known with the acronym LDD (Lightly Doped Drain). Between the source S1 and the drain D1 regions of the N-MOS transistor there is a channel region 12 which includes a N type doped layer 9 (N-layer) which extends from the upper surface 5 and remains within P-well region 6.

In the same way, the P-MOS transistor comprises active regions (of P type) such as one source region S2 and a drain region D2 which extend from the upper surface 5 within N-well region 7 and have a doping opposite to that of such region. The source region S2 (drain D2) comprises a highly doped source pocket 16 (of drain 17) of P+ type and a first lightly doped source region (second region) 18 (of drain 19) of P− type. Between the source S2 and the drain D2 regions of P-MOS transistor there is a channel region 20 which comprises a doped P type layer 15 (Player) which extends from the upper surface 5 and remains within region N-well 7.

N-MOS and P-MOS transistors comprise a respective layer of electrically insulating material 21 (for instance silicon dioxide SiO2) laid upon the upper surface 5 and which extends over channel regions 12, 20. The dioxide layer 21 of each transistor is overlapped by a respective layer of electrically conductive material, preferably polysilicon adequately doped.

N-MOS transistor particularly comprises a gate polysilicon layer 22 which has a doped P+ type (that is, highly doped) central region 23 and, optionally two doped N+ type side regions 24. The P-MOS transistor comprises a polysilicon layer 25 that has regions doped in a complementary way with polysilicon 22, that is a N+ type central region and, optionally two P+ type side regions 27.

It is to be noted that doped layers 9 and 15 in each transistor of FIG. 1, show a doping opposite to that of the central regions 23 and 26 of the gate polysilicon layers, 22 and 25, and of a type similar to that of the respective first and second active regions. Further the central regions of the polysilicon layers 23 and 26 are more intensively doped with respect to corresponding doped layers 9 and 15.

The electronic device of FIG. 1 further comprises dielectric side spacers 28,29,30,31 (usually of silicon dioxide) positioned, both for N-MOS transistor N-MOS and for the P-MOS one, of the silicon dioxide 21 and on the sides above the polysilicon gate layers 22 and 25. Further the dielectric spacers 28,29,30,31 are, respectively, positioned above the lightly doped regions 13,14,18,19.

For instance the described structure of the MOS transistors comprises a further thick layer of silicon dioxide (not shown) to adequately cover the gate polysilicon layers 22 and 25 and adequate metallization (not shown) which constitute the drain, source and gate electric terminals. Such further silicon dioxide layer and the metallizations can be made in the manners and the forms known to a person skilled in the art.

The previously described N-MOS and P-MOS transistors are both buried channel transistors, that is they are such during operation that conductivity occurs within the channel regions 12,20, at a preselected distance from the upper surface 5.

Specifically, the conduction channel extends to a predefined distance (that is a non zero distance) from those interface upper surface portions 5 between the doped layers 9,15 and the respective layer of silicon dioxide 21 (in the following, portions designated by Si—SiO2 interface).

In other words, for both MOS transistors of FIG. 1, the conduction channel does not extend in the Si—SiO2 interface surface but in depth with respect to the interface itself.

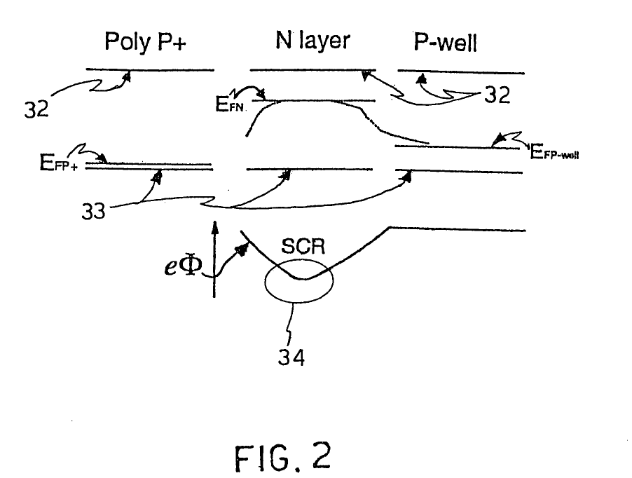

The principles upon which the operation of the buried channel transistor N-MOS is based in accordance with the described embodiment of the invention are obvious to the person skilled the art from the analysis of the energy bands diagram shown in FIG. 2. Similar considerations are valid for the P-MOS transistor as those relative to the N-MOS transistor.

FIG. 2 schematically shows three energy bands diagrams relative to three different zones of the N-MOS transistor: a first diagram indicated with Poly P+, refers to the polysilicon 22 central region 23, a second diagram called N layer, refers to doped layer 9; a third diagram, P-well, refers to P-well region 6.

In the FIG. 2 diagram one finds a minimum conduction band energy level 32, a maximum valence band energy level 33 of the three regions considered and the Fermi energy levels EFP+, EFN, EFP-well relative to the polysilicon central region 23 (Poly P+), to the doped layer 9 (N-layer) and to the P-well region 6, respectively. Further, FIG. 2 shows the pattern in the doped layer 9 (N-layer) of the electrons potential energy which shows a minimum 34. Given that the polysilicon 23 (Poly P+) and the P-well region 6 have a conductivity tied to the holes the respective Fermi energetic levels, that is EFP+ and EFP-well, are close to the maximum valence band energy level 33, while the N type doped layer 9, whose conductivity is tied to the electrons has a Fermi energetic level EFN close to the conduction band minimum energy level 32. Such energetic levels distribution results in a depletion effect which reduces the doped layer 9 free charge carriers, both near the Si—SiO2 interface, with the silicon dioxide 21, and in proximity of the doped layer itself 9 junction with the P-well region 6. In other words, two regions substantially depleted of free carriers are formed: a first region is the one that extends between the polysilicon region 23 and the doped layer 9 (between which dioxide 21 is sandwiched) and the second is that between the doped layer 9 and P-well region 6. Consequently, inside the doped layer 9 (N-layer) takes place a zone wherein the electrons potential energy eφ is minimum (curved section 34 of FIG. 2) at a specific distance from the Si—SiO2 surface interface. It is this area itself with minimum energy for the electrons which is adapted to form the buried channel of the transistor.

To demonstrate that the N-MOS transistor of the present invention is capable to operate as a buried channel transistor computer simulations have been carried out comparing a buried channel N-MOS transistor, of the above described type with a surface channel N-MOS transistor of a conventional type. For these simulations dopings of the active regions, of the doped layer and of the gate polysilicon layer have been considered similar to the ones indicated in the following.

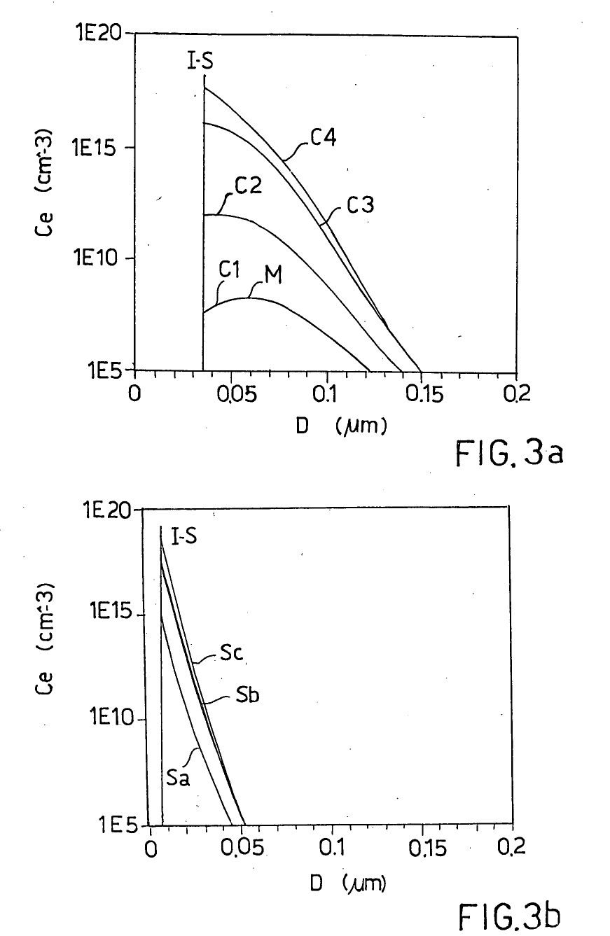

In particular, in these simulations the channel region 12 electrons concentration variation has been evaluated as a function of the distance from the Si—SiO2 interface. In FIG. 3a is charted the pattern of Ce electrons concentration (expressed in log scale) as a function of distance D (expressed in micron) from the Si—SiO2 interface surface (indicated by I—S in the figure) for a buried channel N-MOS transistor in accordance with one embodiment of the invention. In FIG. 3a four different patterns of the electrons concentration, (C1-C4 curves) are shown, for voltage values applied to the transistor gate terminal between 0.3V (C1 curve) and 1.2V (C4 curve).

Similarly, FIG. 3b shows Sa-Sc curves relative to the Ce electrons concentration for gate voltage values between 0.3V (Sa curve) and 1.2V (Sc curve) of a conventional surface channel N-MOS transistor.

In particular, for the buried channel N-MOS transistor (FIG. 3a) the C1 curve shows an electron concentration peak M at a distance from the Si—SiO2 surface larger than the other C2-C4 curves. In particular, the peak M is at a distance D of about 60 nm. For increasing values of the voltage applied to the gate terminal, curves C2,C3,C4 show the respective concentration maximum ever more in proximity of the Si—SiO2 interface I—S. From these results it is possible to understand that the buried channel formation is favored using gate voltages near the voltage threshold value of the transistor itself.

Referring to FIG. 3b relative to the surface channel transistor, it is to be noted that the maximum electrons concentration is obtained just at the Si—SiO2 (I—S) interface for all gate tension levels used in the simulations.

In the following a method for the manufacturing of N-MOS and P-MOS transistors according to an embodiment of the present invention is described. In the following description the same reference numbers will be used to indicate identical or similar members to the already defined ones.

The method described can be carried out with CMOS VLSI (Very Large Scale Integration) technology having nominal width characteristics (that is masks and implantations widths) greater or equal to 0.35 μm, but is also compatible with other integration technologies. For instance, the method is compatible with CMOS ULSI (Ultra Large Scale Integration) technology having masks widths greater or equal to 0.18 μm.

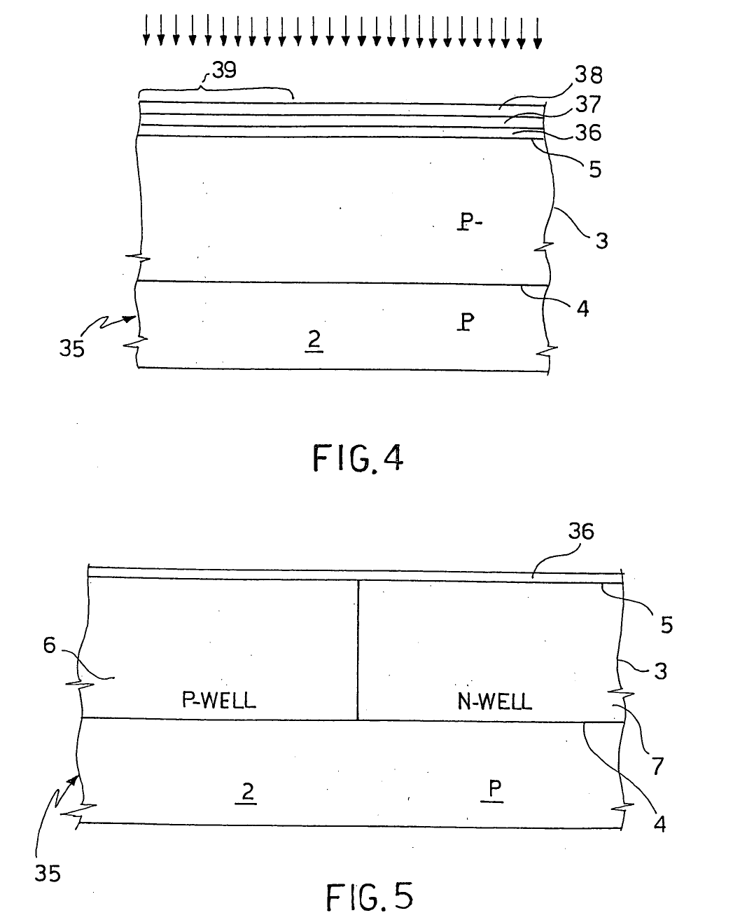

According to the example of FIG. 4, chip 35 is of a P_P-type, that is of the type usually used for CMOS platforms, and it comprises the P type silicon substrate 2 (that is averagely doped) and the P-type epitaxial layer 3 (of silicon) grown on substrate 2 with epitaxial technologies.

The epitaxial layer 3 has a thickness of a few microns and shows a resistivity equal to a few Ω*μm, about one thousand times greater than that of layer 2.

The epitaxial layer P-well and N-well regions 6 and 7 are formed by conventional photolithographic technologies. For instance to realize P-well region 6 a thin layer of silicon dioxide 36 (padox) is initially deposited and is covered after by a light sensitive polymeric material layer 37 called photoresist. The photoresist layer 37 is partially irradiated with a radiation of a suitable wavelength (for instance ultraviolet radiation o X rays) through an appropriate photomask 38 transparent to such a radiation in correspondence to zone 39 of FIG. 4. The irradiated portion of photoresist may be chemically dissolved during the subsequent step, called the development step, while the remaining not exposed to the radiation is not dissolved.

At this point, a preselected quantity of a P type doping impurity (for instance boron) is implanted through the oxide layer 36 not protected by the photoresist in epitaxial layer 3 to form P-well region 6. A subsequent annealing step is utilized to activate the boron dopant which has been implanted.

Characteristics of P-well region 6 (visible in FIG. 5) are a thickness in the order of μm and a concentration of implanted impurities of the order of 1017-1018 atoms/cm3. Through a similar process, but this time with a photomask transparent to radiation only in correspondence of the remaining epitaxial layer 3 not yet implanted, an N type (for instance phosphorus) dopant amount is implanted and diffused to realize the N-well region 7.

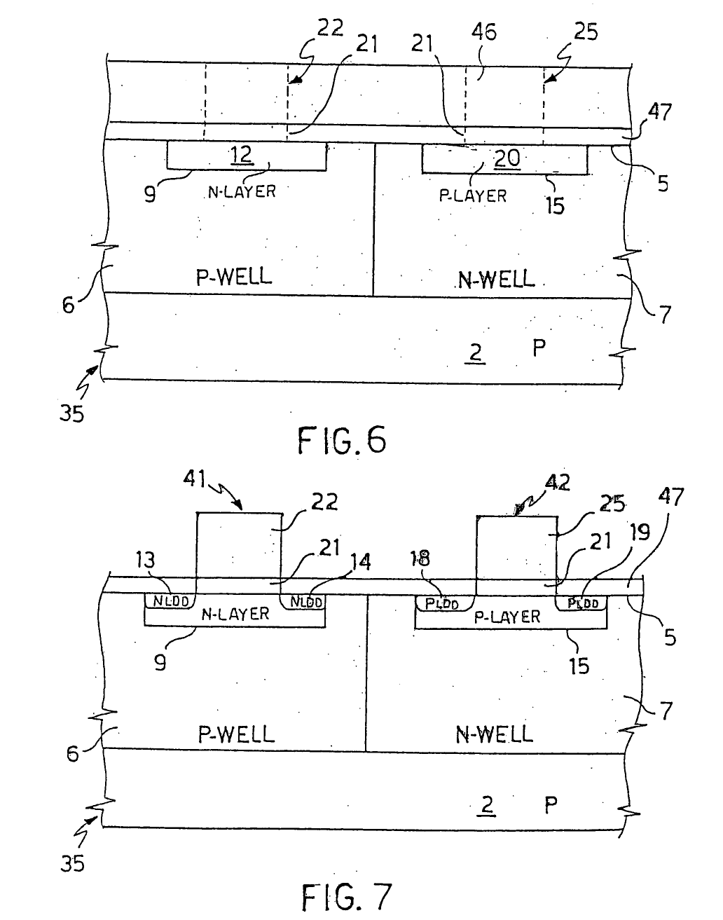

The doped layers 9 and 15 (shown in FIG. 6) are created in the P-well and N-well regions 6,7, respectively with photolithographic processes similar to the above ones.

The doped layer 9 may have an impurities concentration similar to that of the P-well region 6, but of N type and a depth much lower than that of such region. A similar type of consideration is valid for doped layer 15 and N-well region 7.

Later, on the upper surface 5 of chip 35 an oxide layer 47 is grown and, over this, a polysilicon layer 46 is formed.

Starting from the polysilicon layer 46 the gate polysilicon layers 22, 25 are defined, through a photolithographic process similar to the preceding ones and a selective etching, adapted to form gate electrodes (in all indicated with 41 and 42) of the two buried channel transistors.

In particular, the etching removes all of the polysilicon 46 with the exception of the one corresponding to the channel regions 12,20 of N-MOS and P-MOS transistors.

Further, the oxide 47 includes the gate oxide layers 21 of the two transistors.

Then, as shown in FIG. 7 the lightly doped regions 13,14,18,19 are formed on chip 35 through consecutive ionic implantations through several photomasks.

Specifically the lightly doped regions 13,14 are obtained by implanting phosphorus in an amount of the order of 1013 atoms/cm2, while for the lightly doped regions 18,19 boron is implanted always with a dose of the order of 1013 atoms/cm2.

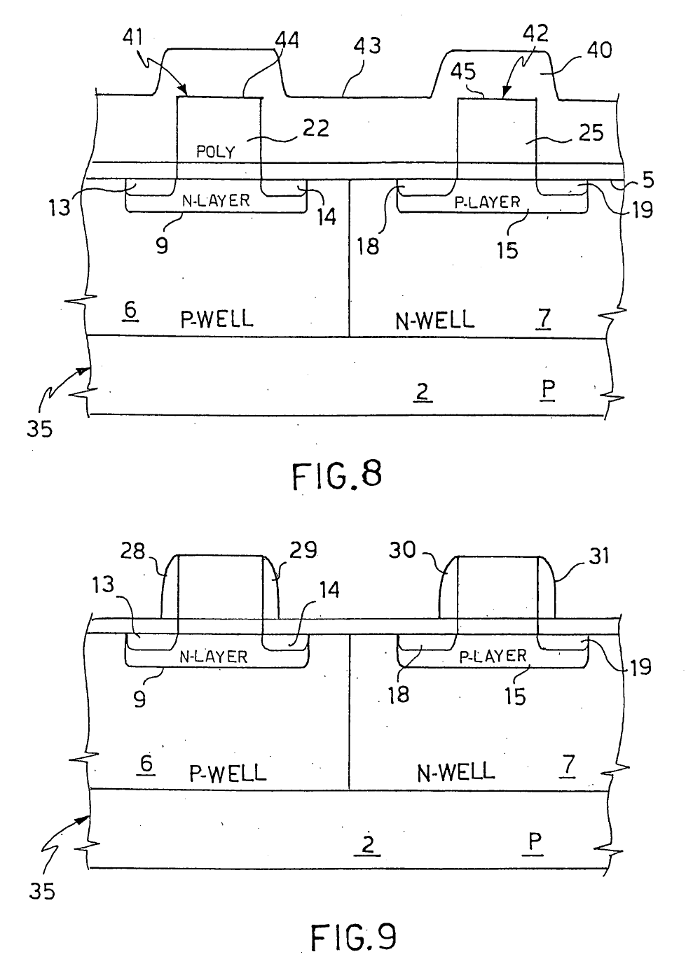

The method of the described embodiment of the invention goes on with the formation of the side dielectric spacers 28,29,30,31 which are formed using technologies usually employed to realize side spacers in MOS transistors. In greater detail and referring to FIG. 8, on the integrated structure shown in the prior FIG. 7 a layer of dielectric material 40 is deposited in such a way as to cover completely the transistors gate electrodes 41,42 and the remaining upper surface 5. Layer 40 is made up by an insulating material such as, for example silicon dioxide or, preferably silicon nitride and may be deposited from vapor phase (CVD technology, Chemical Vapor Deposition).

After the deposition step an etching is carried out, preferably a “dry etching” to remove suitable portions of the nitride layer 40 and, particularly, to remove those portions located above layers 22,25 of the polysilicon gate in such a way as to form some openings which expose a free surface of said layers.

The dry etching is of anisotropic type and it foresees the irradiation of surface 43 of layer 40, opposite the upper surface 5 of chip 35 with a ionic beam for a preselected time period such as to expose free surfaces 44 and 45 of polysilicon 22 and 25, forming at the same time the side spacers 28,29,30,31 (visible in detail in FIG. 9).

It is to be noted that the realization modes of such spacers are easily determined by someone skilled in the art on the basis of the above description.

As shown in FIG. 9, spacers 28 and 29 are overlaid, respectively, to the lightly doped first region 13 and second region 14, while spacers 30 and 31 are overlaid to the slightly doped third region 18 and fourth region 19.

The following step according to one embodiment of the invention provides the realization of highly doped (of N+ type for N-MOS transistor and of P+ type for the P-MOS transistor) source and drain pockets at the same time of the doping of the respective gate polysilicon layers.

The method according to this embodiment of the invention, foresees a step of formation of a photoresist layer 48 located over chip 35 and a masking step followed by a etching step. The etching step defines the source and drain regions of the N-MOS and a central region of the P-MOS complementary transistor polysilicon gate central region.

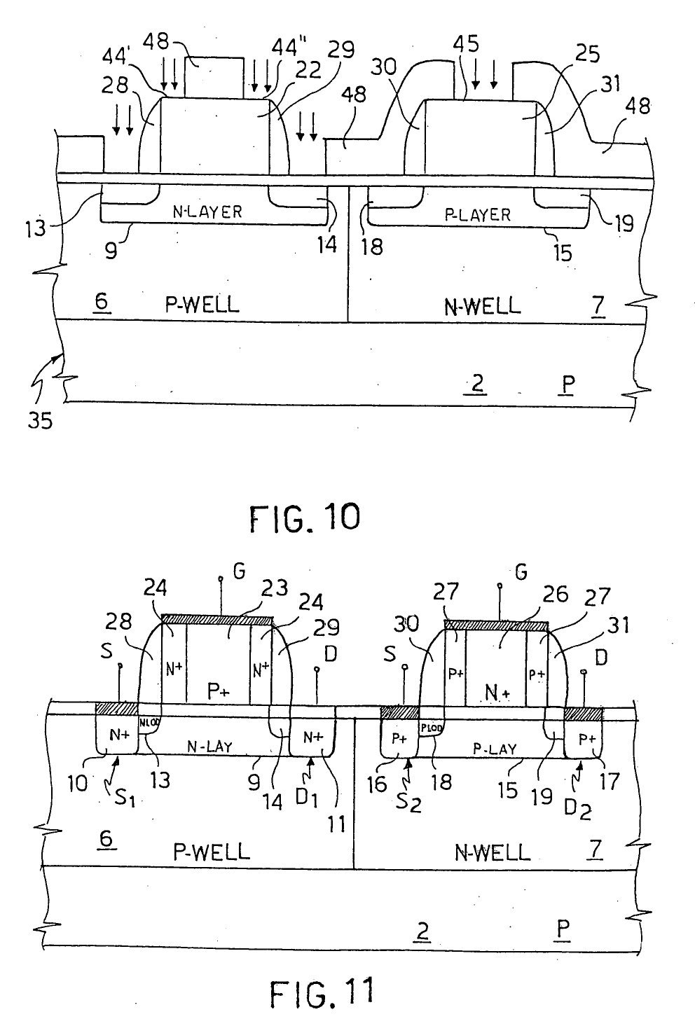

In greater detail, the etching removes photoresist 48 located on the sides of spacers 28,29 and one portion located on the gate polysilicon 25 layer surface 45 (see FIG. 10) defining corresponding openings.

Advantageously, a remaining photoresist 48 layer located on the polysilicon gate 22 of N-MOS transistor is such a way as not to extend beyond the outer edges of the dielectric spacers 28,29 and therefore is such not to overlap chip zones adapted to form source 10 and drain 11 regions. Particularly such photoresist layer 48 shows smaller dimensions than those of the underlying gate polysilicon layer 22, exposing surface portions 44′ and 44″ of surface 44.

In such a way, a conventional ionic implantation introduces a N+ type dopant (for instance arsenic) through the openings obtained in the photoresist layer 48, obtaining source and drain pockets 10, 11 and, at the same time, the polysilicon layer 25 central part. Further the implantation of arsenic through surface portions 44″ and 44″, realizes the N+ type central regions 24 inside the polysilicon layer 22.

The source 10 and drain 11 pockets are implanted with amounts of the order of 1015 atoms/cm2.

The process just described is applied in a similar manner to the P-MOS transistor taking care of removing suitable portions of a further photoresist layer (not shown and similar to layer 48) set along the sides of spacers 30,31 and a portion of the photoresist layer itself set over surface 44 of N-MOS polysilicon gate 22. A following implantation step of a dopant (for instance, boron) permits to realize source 16 and drain 17 pockets and to dope the gate polysilicon layer 22 central region 23.

Similarly to what has been discussed for N-MOS, transistor an only partial coverage of the P-MOS transistor of the gate 25 polysilicon layer determines the formation of P+ type side regions 27 inside the corresponding polysilicon layer 25.

It is to be noted that according to the embodiment of the method outlined above the doping of the gate polysilicon layer 25 (22) of the P-MOS transistor (N-MOS) and that of the source and drain pockets 10, 11 (16, 17) of active regions S1 and D1 (S2 and D2) of N-MOS transistor (P-MOS) takes place in one implantation step and, advantageously during the same masking step which uses the same layer of protective material provided with suitable openings.

The position of spacers 28,29,30,31 is particularly advantageous because it allows the shielding of the lightly doped lower regions from following implants of drain and source regions of N-MOS and P-MOS transistors. Further the presence of the slightly doped regions (that is with reduced conductivity) permits to increase the break voltage that is to increase the maximum voltage value of the transistor.

It is to be noted, further, that the presence of side regions 24 and 27 with opposite doping in the polysilicon gate layers 22 and 25 does not alter in a significant manner the correct operation of the two buried channel N-MOS and P-MOS transistors.

The method according to the described embodiment of the invention may also comprise a conventional step for the realization of contact regions to contact drain 11,17 and source regions 10,16 of the transistors, and also suitable metallization among which there are those of drain, of source and of gate outlined in FIG. 11 with three electric terminals D, S and G.

It is to be noted that the above described method is particularly advantageous because it permits to realize both a buried channel N-MOS transistor and a buried channel P-MOS transistor on the same silicon chip using a reduced number of photolithographic steps (maskings).

Specifically the doping of the polysilicon gate of each N-MOS and P-MOS transistors during the source and drain pockets implantation step of the complementary transistor permits to make such polysilicon of opposed conductivity as corresponding doped layer 9 and 15 through a single implantation step.

Referring to electronic device 1 of the invention, it has been observed that the reduced interaction of the charge carriers of the channel region (electrons for the N-MOS transistor and holes for the P-MOS transistor) with the surface layers of the Si—SiO2 interface favors the increase of the carriers mobility and the reduction of the low frequency noise.

Therefore it has been observed that for electronic device 1 according to the described embodiment of the invention, the obtained performances in terms of charge carriers mobility and low frequency noise are higher than those which may be achieved with conventional integrated electronic devices, which use buried channel P-MOSs and surface channel N-MOSs.

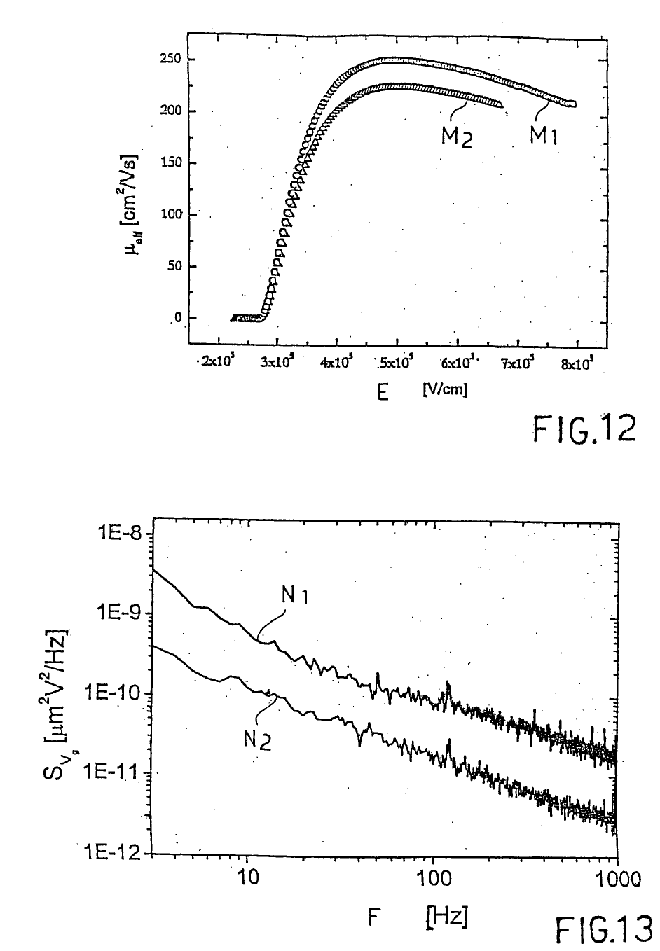

In this context, the diagrams of FIGS. 12 and 13, obtained experimentally, compare the mobility of the charge carriers (electrons) and the noise spectral density of a buried channel N-MOS transistor and of a surface channel N-MOS transistor. Specifically, in FIG. 12 the effective electrons mobility μeff is mapped as a function of a cross electric field E applied in the channel region and variable, for instance from 2*105 V/cm to 8*105 V/cm; in such a case, the mobility for the buried channel transistor (M1 curve) is 10% greater than that of the surface channel transistor (M2 curve) when the field is greater than 4*105 V/cm. In FIG. 13 is shown, in log scale, a measurement of the noise spectral density SVg referred to the input as a function of frequency F both for the buried channel transistor (N2 curve) and for the surface channel one (N1 curve). The noise spectral density SVg is normalized to the gate area size of the transistors and for both measurements the gate voltage is close to the voltage threshold value. In the frequency range 1-1000 Hz is observed a reduction of about an order of magnitude of the noise density SVg for the buried channel N-MOS transistor as compared with the surface channel N-MOS.

The electronic device 1 of the invention may be applied to different application types, but it proves particularly advantageous for analog applications. Particularly, the electronic device 1 may be the input circuit block of an audio amplifier. It is evident for a person skilled in the art how to implement, starting from the above description, an audio amplifier input circuit block having a plurality of buried channel N-MOS and P-MOS transistors of the type of the invention and connected in a suitable manner. For example an audio amplifier input block comprises a differential stage with a mirror load. In such case the MOS transistors coupled through the source terminal which constitute the differential stage may be of buried channel N-MOS type (similar to that described in detail above) while the transistors which form the mirror load of the differential stage may be buried channel P-MOS (similar to the P-MOS transistor described earlier).

Advantageously, such audio amplifier input circuit block of the type described above will have a significantly limited low frequency noise, because both the N-MOS transistors, and the P-MOS ones, which it includes are of a buried channel type and ensure the limitation of such a noise type.

For description completion we affirm that, in particular the N-MOS transistors which form this differential stage become operative with high drainsource voltages, in a way to guarantee high transconductances, even with gate voltages close to their threshold voltage in a way as to guarantee high gains and limit dissipations. Using gate voltages close to the threshold voltage is in accordance with an aspect of the present invention, because it helps the creation of a conduction channel which may result buried with reference to the Si—SiO2, surface interface as already set forth with reference to FIG. 3a.

Further, some steps of the manufacturing method described may be used to integrate on the same chip also surface channel N-MOS and P-MOS transistors (not shown) besides the buried channel ones.

In particular, as the person skilled in the art shall understood, for the realization of surface channel MOS will be used substantially the same above described steps with the exception of the realization step of doped layers 9 and 15. Further, for the integration of such surface channel transistors contrary to what has been done for realizing the buried channel transistors a N+ type polysilicon gate for the N-MOS transistors and a P+ type polysilicon gate for the P-MOS transistors are formed.

Obviously the person skilled in the art will be able to bring several changes and modifications to the electronic device and the manufacturing method described above, with the object of satisfying contingent and specific requirements, all nevertheless within the scope of protecting the invention, such as defined by the following claims.

1. Electronic device integrated in a chip of semiconductor material comprising:
at least one first buried channel MOS transistor formed in said chip,
at least one second MOS transistor made in said chip, of a type complementary to the at least one first transistor,
characterized in that said at least one second transistor is of a buried channel type.

2. Device according to claim 1, wherein each of said at least one first and at least one second transistors comprises:
a polysilicon gate layer superimposed on a gate electrically insulating material layer laid on an upper surface of the chip;
a first and a second active regions which extend from the upper surface of said chip towards the inside of the same,
a doped layer which extends between said first and second active regions adapted to include a conduction channel, said doped layer having a doping homologous to that of the respective first and second active regions.

3. Device according to claim 2, wherein said first and second active regions, said doped layer are formed inside a doped well region of the chip having a doping opposite to that of the active regions.

4. Device according to claim 2, wherein said polysilicon gate layer comprises a central region having a doping opposite to that of the respective doped layer and two side regions having a doping homologous to that of the respective first and second active regions.

5. Device according to claim 4, wherein said central region and said side regions of the polysilicon gate layer and portions of said active regions are highly doped.

6. Device according to claim 4, wherein said central region of said polysilicon gate layer is more highly doped than the respective doped layer.

7. Device according to claim 2, wherein said active regions comprise further portions lightly doped.

8. Device according to claim 2, wherein said polysilicon gate layer and said doped layer give origin to a depletion effect which reduces the free charge carriers at least in one portion of the doped layer.

9. Device according to claim 2, wherein the conduction channel of said at least one first and one second transistors is formed inside said doped layer at a preselected distance from an interface surface between the electrically insulating material and the doped layer.

10. Device according to claim 1, wherein said device is an input circuit block of an audio amplifier comprising a differential stage and a current mirror load and comprising a first plurality of buried channel MOS transistors and a second plurality of buried channel MOS transistors complementary to those of the first plurality.

11. Manufacturing method of an electronic device integrated in a semiconductor material chip, the method comprising the steps of:
forming in the chip at least a first buried channel MOS transistor,
forming in the chip al least a second buried channel MOS transistor of a type complementary to said first transistor,
characterized by the fact that said at least one second transistor is of the buried channel type.

12. Method according to claim 11, comprising a first chip doping step through a first type dopant to form at least portions of the active regions of said at least one first transistor and to dope at least one portion of a polysilicon gate layer of said at least one second transistor, the first doping step being carried out by a single implantation of the first type dopant.

13. Method according to claim 12, comprising a second chip doping step through a second type dopant, opposite to the first type one, to form at least portions of the active regions of said at least one second transistor and to dope at least one portion of a polysilicon gate layer of said at least one first transistor, the second doping step being carried out trough a single implantation of the second type dopant.

14. Method according to claim 13, wherein the implantation of the second type dopant takes place through a single layer of protective material provided with openings corresponding to said active regions of said at least one second transistor and through an opening corresponding to a free surface of said polysilicon layer of the at least one first transistor.

15. Method according to claim 14, wherein said single protective material layer is such to expose at least one surface portion of the polysilicon layer of the at least one second transistor, and wherein said second doping step provides the implantation through said at least one surface portion of the second type dopant determining the formation of at least one side portion of said polysilicon layer of the at least one second transistor having a doping opposite to a central region of the same polysilicon layer obtained by the first doping step.

16. Method according to claim 13, further comprising implantation and diffusion steps in the chip of a first type dopant to form a doped layer which extends between said active regions of the at least one first transistor, said dopant being of a type opposite to the dopant of the polysilicon gate layer of said first transistor.

17. Method according to claim 14, comprising a formation step of a doped well region of the chip wherein are included said active regions of the at least one first transistor and said doped layer, the well doped region being doped with a dopant of a type opposite to that of the doped layer.

18. Method according to any of the preceding Claims, further comprising steps of:
forming an electrically insulating material layer on the upper surface of said chip,
forming a conductive material layer laid over said electrically insulating material layer,
defining starting from said electrically insulating and conductive material layer, gate electrodes of said at least one first and at least one second transistors.

19. Method according to claim 11, further comprising one step of forming at least one surface channel MOS transistor integrated in said chip of semiconductor material.

20. Method according to claim 11, that may be carried out according a VLSI (Very Large Scale Integration) or ULSI (Ultra Large Scale Integration) integration technology.

21. A transistor formed in a well region in a substrate, the well region having a first conductivity type and the transistor comprising:
a source region having a second conductivity type formed in the well region;
a drain region having the second conductivity type formed in the well region;
a gate insulating layer formed on a surface of the well region between the source and drain regions;
a control gate region having the first conductivity type formed on the gate insulating layer; and
a doped region having the second conductivity type formed in the well region and adjoining the source and drain regions, the doped region forming a channel region at a distance from an interface between the doped region and the gate insulating layer.

22. The transistor of claim 21 further comprising:
a first lightly doped region of the second conductivity type formed in the doped region adjoining the source region; and
a second lightly doped region of the second conductivity type formed in the doped region adjoining the drain region.

23. The transistor of claim 21 wherein the control gate and doped regions have approximately the same doping profiles.

24. The transistor of claim 21 wherein the control gate region further comprises regions having the second conductivity type formed adjoining the region having the first conductivity type.

25. A method of forming a transistor in a substrate, the method comprising:
forming a well region having a first conductivity type in the substrate;
forming a source region having a second conductivity type in the well region;
forming a drain region having the second conductivity type in the well region;
forming a gate insulating layer on a surface of the well region between the source and drain regions;
forming a control gate region having the first conductivity type on the gate insulating layer; and
forming a channel between the source and drain regions, the channel being at a distance from an interface between the well region and the gate insulating layer.

26. The method of claim 25 wherein forming the channel comprises forming a doped region of the second conductivity type in the well region and adjoining the source and drain regions.

27. The method of claim 25 wherein the control gate and doped regions are formed having approximately the same doping profiles.
